(19) United States
(12) Patent Application Publication
(10) Pub. No.: US 2023/0024030 A1
(43) Pub. Date: Jan. 26, 2023

(54) METHOD OF MANUFACTURING PHASE CHANGE MEMORY AND PHASE CHANGE MEMORY

(71) Applicant: Beijing Advanced Memory Technology Co., Ltd., Beijing (CN)

(72) Inventors: Dong GAN, Beijing (CN); CHUNG-HON LAM, Beijing (CN)

(21) Appl. No.: 17/814,236

(22) Filed: Jul. 22, 2022

(30) Foreign Application Priority Data
Jul. 23, 2021 (CN) 202110833924.X

(51) Int. Cl. H01L 45/00; H01L 27/24

(52) U.S. Cl. CPC H01L 45/06; H01L 27/2409; H01L 45/145; H01L 45/1608

(57) ABSTRACT

The present invention discloses a method for manufacturing a phase change memory and a phase change memory. The method comprises: forming a first wafer having a semiconductor-on-insulator structure; forming a memory material layer on the semiconductor-on-insulator structure; and forming a first metal material layer on the memory material layer to form a first semiconductor element.

### CROSS-REFERENCE TO RELATED APPLICATION

This application claims priority to China Application Serial Number 202110833924.X, filed Jul. 23, 2021, which is herein incorporated by reference.

### BACKGROUND

### Field of Invention

The present invention relates to a method of manufacturing a phase change memory and a phase change memory.

### Description of Related Art

Electronic products (e.g., mobile phones, tablets, and digital cameras) often have memory elements that store data. Conventional memory elements can store information through storage nodes of memory units. Among them, the phase change memory uses resistance states (e.g., high resistance and low resistance) of the memory element to store information. The memory element may have a material that can be switched between different phase states (e.g., a crystalline phase and an amorphous phase). The different phase states enable the memory unit to have different resistance states for representing different values of stored data.

Generally, an accurate alignment is required when manufacturing a phase change memory, so that the process is complicated and difficult to be controlled, and the manufacturing cost of the phase change memory is increased. Moreover, a word line metal layer, a phase change material layer, a bit line metal layer and the like are directly formed on a wafer having, such as, CMOS, and the characteristic of the CMOS is degraded by a high temperature during the crystallization of the phase change material layer. Therefore, a novel and efficient process for manufacturing a phase change memory is urgently needed.

### SUMMARY

An object of the present invention is to provide a method of manufacturing a phase change memory and a phase change memory capable of solving one or more deficiencies of the related art.

In one embodiment, the present invention provides a method of manufacturing a phase change memory, comprising: forming a first wafer having a semiconductor-on-insulator structure; forming a memory material layer on the semiconductor-on-insulator structure; and forming a first metal material layer on the memory material layer to form a first semiconductor element.

In some embodiments, forming the first wafer comprises: forming an insulating layer on a substrate; forming a semiconductor layer on the insulating layer to form the semiconductor-on-insulator structure; and performing N-type and P-type doping on the semiconductor layer to form a selector.

In some embodiments, the method further comprises: forming a memory array in the first semiconductor element, the memory array comprising a plurality of memory units formed in the memory material layer, a plurality of selector units formed in the semiconductor-on-insulator structure, and a plurality of first metal regions formed in the first metal material layer.

In some embodiments, the method further comprises: forming a second semiconductor element, wherein the second semiconductor element comprises a second wafer having a first contact region and a second contact region; and flipping the first semiconductor element and bonding a first surface of the first semiconductor element with a first surface of the second semiconductor element.

In some embodiments, the method further comprises: removing the substrate to expose the insulating layer after bonding the first surface of the first semiconductor element with the first surface of the second semiconductor element.

In some embodiments, removing the substrate comprises: grinding, polishing and/or etching a second surface of the first semiconductor element to expose the insulating layer.

In some embodiments, bonding the first surface of the first semiconductor element with the first surface of the second semiconductor element comprises: aligning and connecting the first metal region of the first semiconductor element with the first contact region of the second semiconductor element.

In some embodiments, the method, after removing the substrate to expose the insulating layer, further comprises: forming a first contact hole in the insulating layer; and forming a second metal material layer in the insulating layer, wherein the second metal material layer is connected to the plurality of selector units, and connected to the second contact region of the second semiconductor element through the first contact hole.

In some embodiments, the method further comprises: before flipping the first semiconductor element, forming a first connection channel in the first semiconductor element comprising the memory array, wherein the first connection channel comprises a first connection region and a second connection region electrically isolated from each other, and the first connection region is connected to the first metal region through a first connection hole.

In some embodiments, bonding the first surface of the first semiconductor element with the first surface of the second semiconductor element further comprises: aligning and connecting the first connection region and the second connection region of the first semiconductor element with the first contact region and the second contact region of the second semiconductor element, respectively.

In some embodiments, the method, after removing the substrate to expose the insulating layer, further comprises: forming a second contact hole in the insulating layer; and forming a second metal material layer in the insulating layer, wherein the second metal material layer is connected to the plurality of selector units, and connected to the second contact region of the second semiconductor element through the second connection region and the second contact hole.

In some embodiments, the method, before flipping the first semiconductor element, further comprises: forming a second connection channel in the first semiconductor element comprising the memory array, wherein the second connection channel comprises a third connection region connected to the first metal region through a second connection hole; forming a first oxide layer having a first thickness on the third connection region of the first semiconductor element; and forming a second oxide layer having a second thickness on the first contact region and the second contact region of the second semiconductor element.

In some embodiments, the first oxide layer and the second oxide layer comprise same material.

In some embodiments, bonding the first surface of the first semiconductor element with the first surface of the second semiconductor element further comprises: aligning the first oxide layer of the first semiconductor element with the second oxide layer of the second semiconductor element.

In some embodiments, the method, after removing the substrate to expose the insulating layer, further comprises: forming a plurality of third contact holes in the insulating layer; and forming a second metal material layer in the insulating layer, wherein the second metal material layer comprises a plurality of second metal regions having a first portion and a second portion electrically isolated from each other, wherein the first portion of the plurality of second metal regions is connected to the plurality of selector units, and connected to the second contact region of the second semiconductor element through the third contact hole, and wherein the second portion of the plurality of second metal regions is connected to the third connection region of the second connection channel through the third contact hole, and connected to the first contact region of the second semiconductor element through the third contact hole.

In some embodiments, the memory material layer is a phase change memory material layer.

In some embodiments, the memory material layer is a non-volatile memory material layer comprising one or more of a voltage controlled resistor, a memory resistor and a resistor random access memory.

The present invention also provides a phase change memory, comprising: a first semiconductor element comprising a first wafer having a semiconductor-on-insulator structure, a selector formed on the semiconductor-on-insulator structure, a memory material layer formed on the selector, and a first metal material layer formed on the memory material layer.

In some embodiments, the first semiconductor element further comprises a memory array, the memory array comprising: a plurality of memory units formed in the memory material layer; a plurality of selector units formed in the semiconductor-on-insulator structure; and a plurality of first metal regions formed in the first metal material layer.

In some embodiments, the first wafer comprises: an insulating layer formed on a removable substrate, wherein the selector is formed by forming a semiconductor layer on the insulating layer to form the semiconductor-on-insulator structure, and performing N-type and P-type doping on the semiconductor layer.

In some embodiments, phase change memory further comprises: a second semiconductor element comprising a second wafer having a first contact region and a second contact region, wherein the first semiconductor element is flipped and mounted on the second semiconductor element, and a first surface of the first semiconductor element is bonded with a first surface of the second semiconductor element.

In some embodiments, the first metal region of the first semiconductor element is aligned and connected with the first contact region of the second semiconductor element.

In some embodiments, the first semiconductor element further comprises: a first contact hole formed in the insulating layer; and a second metal material layer formed in the insulating layer, wherein the second metal material layer is connected to the plurality of selector units, and connected to the second contact region of the second semiconductor element through the first contact hole.

In some embodiments, the first semiconductor element further comprises: a first connection channel having a first connection region and a second connection region electrically isolated from each other, wherein the first connection region is connected to the first metal region through a first connection hole, and wherein the first connection region and the second connection region of the first semiconductor element are aligned and connected with the first contact region and the second contact region of the second semiconductor element, respectively.

In some embodiments, the first semiconductor element further comprises: a second contact hole formed in the insulating layer; and a second metal material layer formed in the insulating layer, wherein the second metal material layer is connected to the plurality of selector units, and connected to the second contact region of the second semiconductor element through the second connection region and the second contact hole.

In some embodiments, the first semiconductor element further comprises: a second connection channel having a third connection region connected to the first metal region through a second connection hole; and a first oxide layer formed on the third connection region of the first semiconductor element, wherein the first oxide layer of the first semiconductor element is aligned and bonded with a second oxide layer formed on the first contact region and the second contact region of the second semiconductor element.

In some embodiments, the first oxide layer and the second oxide layer comprise same material.

In some embodiments, the first semiconductor element further comprises: a plurality of third contact holes formed in the insulating layer; and a second metal material layer formed in the insulating layer, the second metal material layer comprising a plurality of second metal regions having a first portion and a second portion electrically isolated from each other, wherein the first portion of the plurality of second metal regions is connected to the plurality of selector units, and connected to the second contact region of the second semiconductor element through the third contact hole, and wherein the second portion of the plurality of second metal regions is connected to the third connection region of the second connection channel through the third contact hole, and connected to the first contact region of the second semiconductor element through the third contact hole.

In some embodiments, the memory material layer is a phase change memory material layer.

In some embodiments, the memory material layer is a non-volatile memory material layer comprising one or more of a voltage controlled resistor, a memory resistor and a resistor random access memory.

In some embodiments, the first metal material layer is a metal material layer for forming a bit line, and the second metal material layer is a metal material layer for forming a word line.

According to the present invention, two wafers may be easily aligned and bonded with each other by forming P—N diodes as the selectors using the semiconductor-on-insulator structure, and transferring the layer between the wafers through oxide-oxide melted bonding or oxide-metal mixed bonding, thereby lowering the defect density and leakage without additional risks.

It should be understood that the above general description and the following detailed description are exemplary and are intended to provide a further explanation of the claimed invention.

### BRIEF DESCRIPTION OF THE DRAWINGS

The present invention can be more fully understood by reading the following detailed description of the embodiments and referring to the accompanying drawings:

FIG. 1 is a flow diagram showing a method for manufacturing a phase change memory according to various embodiments of the present invention.

FIG. 2 is a diagram showing a structure of a phase change memory manufactured by the method according to one embodiment of the present invention.

FIGS. 3A to 3D are side views of a first semiconductor element formed in each step of the method according to one embodiment of the present invention.

FIG. 4 is a side view of a second semiconductor element formed in the method according to one embodiment of the present invention.

FIGS. 5A to 5C are side views of the first semiconductor element and the second semiconductor element bonded with each other in each step of the method according to one embodiment of the present invention.

FIG. 6 is a side view of a first semiconductor element formed by the method according to another embodiment of the present invention.

FIGS. 7A to 7B are side views of the first semiconductor element and a second semiconductor element bonded with each other in each step of the method according to another embodiment of the present invention.

FIG. 8 is a side view of a first semiconductor element formed by the method according to still another embodiment of the present invention.

FIG. 9 is a side view of a second semiconductor element formed by the method according to still another embodiment of the present invention.

FIGS. 10A to 10C are side views of the first semiconductor element and the second semiconductor element bonded with each other in each step of the method according to still another embodiment of the present invention.

FIG. 11 is a diagram showing a structure of a phase change memory manufactured by the method according to further embodiment of the present invention.

FIG. 12 is a diagram showing a structure of a phase change memory manufactured by a method according to prior art.

### DETAILED DESCRIPTION

In order that the present invention is described in detail and completeness, implementation aspects and specific embodiments of the present invention with illustrative description are presented, but it is not the only form for implementation or use of the specific embodiments of the present invention. The embodiments disclosed herein may be combined or substituted with each other in an advantageous manner, and other embodiments may be added to an embodiment without further description. In the following description, numerous specific details will be described in detail in order to enable the reader to fully understand the following embodiments. However, the embodiments of the present invention may be practiced without these specific details.

Further, spatially relative terms, such as “beneath,” “over,” and the like, may be used herein for ease of description to describe one element or feature's relationship to another element(s) or feature(s) as shown in the figures. The true meaning of the spatially relative terms includes other orientations. For example, when the figure is flipped up and down by 180 degrees, the relationship between one component and another component may change from “beneath” to “over.” The spatially relative descriptions used herein should be interpreted the same.

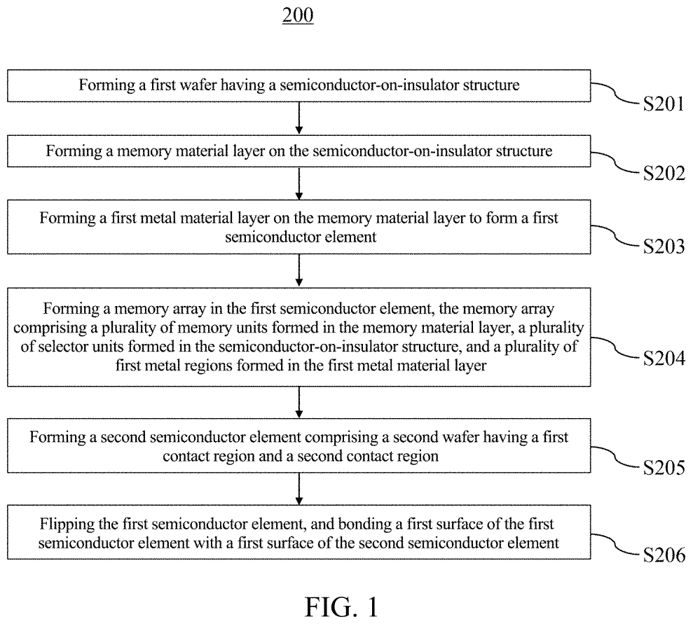

FIG. 1 is a flow diagram showing a method 200 for manufacturing a phase change memory according to various embodiments of the present invention. As shown in FIG. 1, in one embodiment, the method 200 may at least comprise a step S201, a step S202 and a step S203. In another embodiment, the method 200 may further comprise a step S204. In further embodiment, the method 200 may further comprise a step S205 and a step S206.

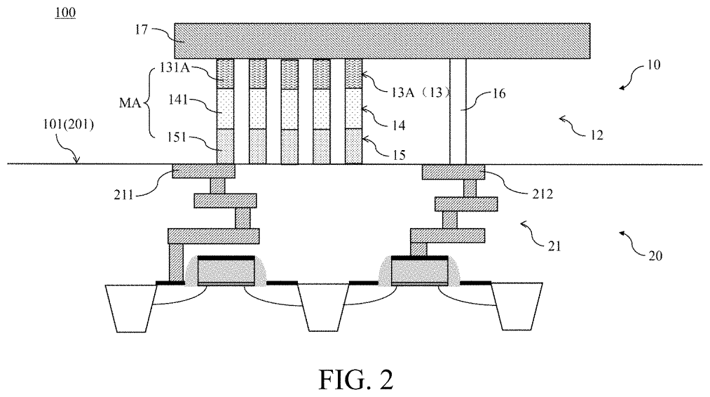

FIG. 2 is a diagram showing a structure of a phase change memory manufactured by the method according to one embodiment of the present invention. As shown in FIG. 2, in one embodiment, the phase change memory 100 may comprise a first semiconductor element 10. The first semiconductor element 10 may comprise a first wafer (not shown) having a semiconductor-on-insulator (SOI) structure, a semiconductor layer 13, a memory material layer 14 and a first metal material layer 15. In one embodiment, the first wafer may comprise an insulating layer 12 formed on a removable substrate, and the semiconductor layer 13 may be formed on the insulating layer 12 to form the SOI structure. In some embodiments, in the SOI structure, a selector 13A may be formed on the semiconductor layer 13 through doping or the like, and the selector 13A may comprise a plurality of selector units 131A, such as, P—N diodes.

In some embodiments, the first semiconductor element 10 may further comprise a memory array MA. The memory array MA, for example, may comprise a plurality of memory units 141 formed in the memory material layer 14, a plurality of selector units 131A formed in the SOI structure, and a plurality of first metal regions 151 formed in the first metal material layer 15.

In some embodiments, the phase change memory 100 may further comprise a second semiconductor element 20. The second semiconductor element 20 may comprise a second wafer 21 having a first contact region 211 and a second contact region 212. The first semiconductor element 10 is flipped and mounted on the second semiconductor element 20, such that a first surface 101 of the first semiconductor element 10 is bonded with a first surface 201 of the second semiconductor element 20.

In some embodiments, as shown in FIG. 2, the first metal region 151 of the first semiconductor element 10 may be aligned and connected with the first contact region 211 of the second semiconductor element 20.

In another embodiment of the present invention, the first semiconductor element 10 may further comprise a contact hole 16 and a second metal material layer 17. The contact hole 16 is formed in the insulating layer 12. The second metal material layer 17 is formed in the insulating layer 12. The second metal material layer 17 is connected to the plurality of selector units 131A, and connected to the second contact region 212 of the second semiconductor element 20 through the contact hole 16.

Hereinafter, the method for manufacturing a phase change memory and a phase change memory manufactured by the method will be explained in details with reference to FIGS. 1 to 11.

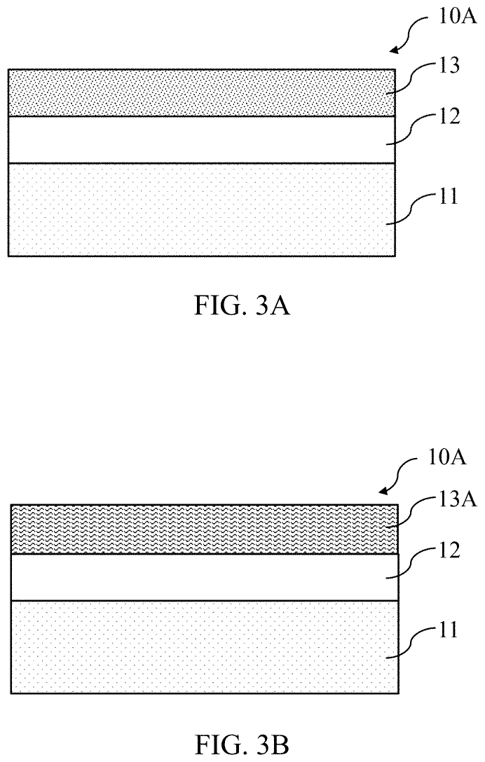

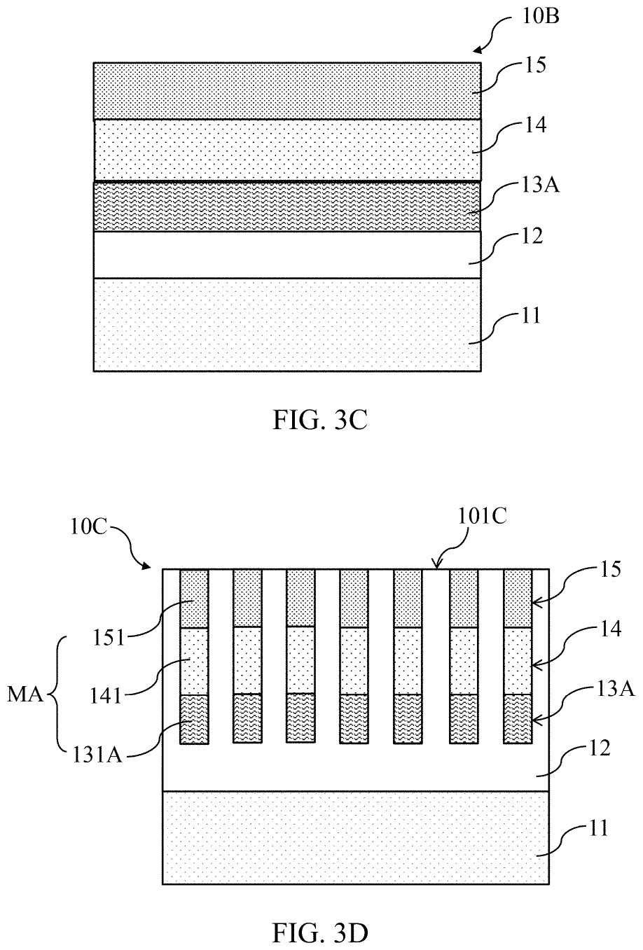

Referring to FIG. 1, in step S201 of the method 200, a first wafer having a semiconductor-on-insulator (SOI) structure is formed. The first wafer, for example, may be a silicon wafer. FIGS. 3A and 3B show the step S201 according to one embodiment of the present invention. As shown in FIGS. 3A and 3B, in one embodiment of the present invention, forming the first wafer 10A may comprise: forming an insulating layer 12 on a substrate 11, and forming a semiconductor layer 13 on the insulating layer 12 to form the SOI structure. Then, N-type and P-type doping may be performed on the semiconductor layer 13 to form the selector 13A, such as, P—N diode. The insulating layer 12, for example, may be a buried oxide (BOX) layer or the like. The substrate 11, for example, may be a silicon substrate or a glass substrate. However, the present invention is not limited thereto, and other substrate may also be used.

Referring to FIG. 1 again, in step S202 of the method 200, a memory material layer is formed on the SOI structure. FIG. 3C shows the step S202 according to one embodiment of the present invention. As shown in FIG. 3C, in one embodiment of the present invention, a memory material layer 14 may be deposited on the selector 13A by physical vapor deposition (PVD), chemical vapor deposition (CVD), atomic layer deposition or the like. In some embodiments, the memory material layer 14 may be a phase change material (PCM) layer, such as a germanium antimony tellurium (GST) layer, and may be formed as memory units in a subsequent process. In other embodiments, the memory material layer 14 may be other non-volatile memory (NVM) material layer, and the present invention is not limited thereto.

Referring to FIG. 1 again, in step S203 of the method 200, a first metal material layer is formed on the memory material layer to form a first semiconductor element. FIG. 3C shows the step S203 according to one embodiment of the present invention. As shown in FIG. 3C, in one embodiment of the present invention, a first metal material layer 15 is deposited on the memory material layer 14 to form a first semiconductor element 10B by physical vapor deposition (PVD), chemical vapor deposition (CVD), atomic layer deposition or the like.

Referring to FIG. 1 again, in step S204 of the method 200, which follows the step S203, a memory array is formed in the first semiconductor element 10B, and the memory array comprises a plurality of memory units 141 formed in the memory material layer 14, a plurality of selector units 131A formed in the SOI structure, and a plurality of first metal regions 151 formed in the first metal material layer 15. FIG. 3D shows the step S204 according to one embodiment of the present invention. As shown in FIG. 3D, in one embodiment of the present invention, a first surface 101C of the first semiconductor element 10B may be patterned to form a plurality of memory units 141 in the memory material layer 14, a plurality of selector units 131A in the SOI structure, and a plurality of first metal regions 151 in the first metal material layer 15. The memory units 141, the selector units 131A and the first metal regions 151 constitute a memory array MA in which data may be stored. Through the step S205, a first semiconductor element 10C comprising the memory array MA may be formed.

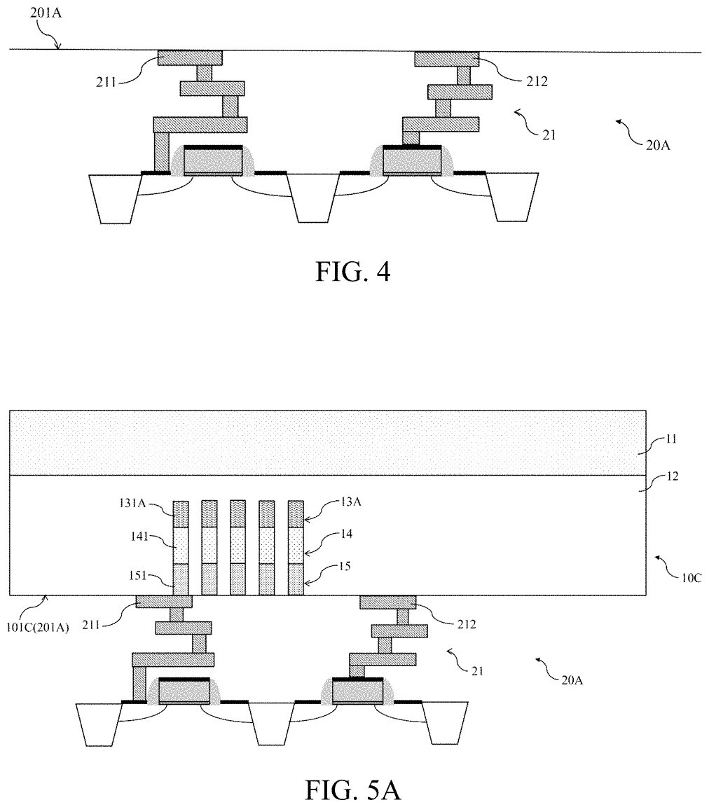

Referring to FIG. 1 again, in step S205 of the method 200, which follows the step S204, a second semiconductor element is formed. The second semiconductor element comprises a second wafer having a first contact region and a second contact region. FIG. 4 shows the step S205 according to one embodiment of the present invention. As shown in FIG. 4, in one embodiment of the present invention, a second semiconductor element 20A may be formed. The second semiconductor element 20A may comprise a second wafer 21 having a first contact region 211 and a second contact region 212. The second semiconductor element 20A has a first surface 201A. In one embodiment of the present invention, the second semiconductor element 20A, for example, may be a CMOS in a front end of line (FEOL) or a wiring in a back end of line (BEOL). For example, the second wafer 21 may be manufactured as a silicon wafer having three metal layers (M3). However, in other embodiments, the second semiconductor element 20A comprising the second wafer 21 may be manufactured differently, and the present invention is not limited thereto.

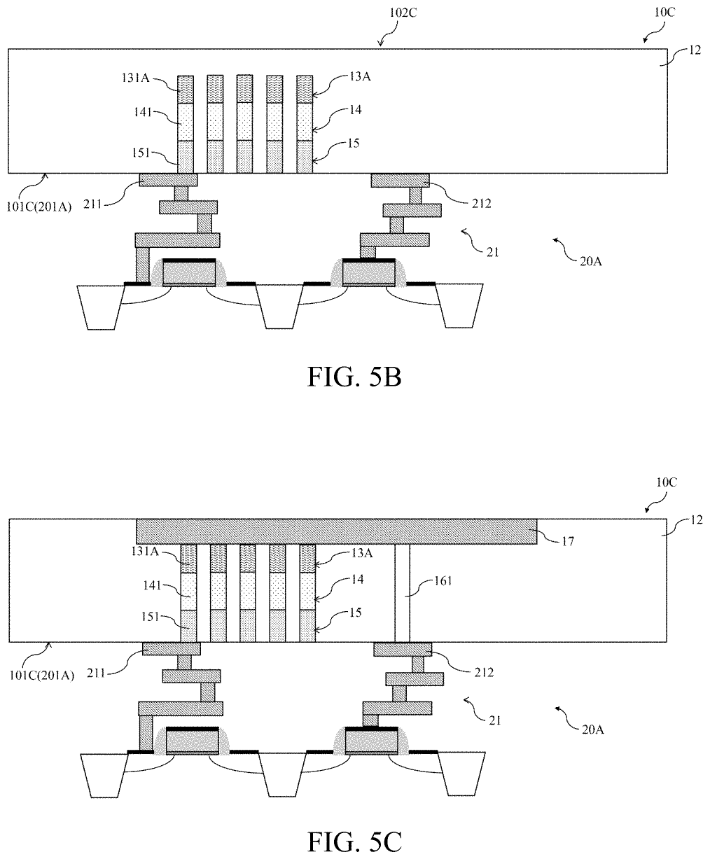

Referring to FIG. 1 again, in step S206 of the method 200, which follows the step S205, the first semiconductor element is flipped, and a first surface of the first semiconductor element is bonded with a first surface of the second semiconductor element. FIG. 5A is shows the step S206 according to one embodiment of the present invention. As shown in FIG. 5A, in one embodiment of the present invention, the first semiconductor element 10C shown in FIG. 4 may be flipped and mounted on the second semiconductor element 20A, such that the first surface 101C of the first semiconductor element 10C is bonded with the first surface 201A of the second semiconductor element 20A. Bonding the first surface 101C of the first semiconductor element 10C with the first surface 201A of the second semiconductor element 20A may further comprise: aligning and connecting the first metal region 151 of the first semiconductor element 10C with the first contact region 211 of the second semiconductor element 20A.

After the bonding process of step S206, as shown in FIG. 5B, the method 200 may further comprise: removing the substrate 11 of the first semiconductor element 10C to expose the insulating layer 12. In some embodiments, the substrate 11 may be removed by grinding, polishing and/or etching a second surface 102C of the first semiconductor element 10C to expose the insulating layer 12.

After removing the substrate 11 to expose the insulating layer 12, as shown in FIG. 5C, the method 200 may further comprise: forming a first contact hole 161 in the insulating layer 12; and forming a second metal material layer 17 in the insulating layer 12. The second metal material layer 17 is connected to the plurality of selector units 131A, and connected to the second contact region 212 of the second semiconductor element 20A through the first contact hole 161. In some embodiments, the first contact hole 161 may be formed by etching and may be filled with a conductive material.

As shown in FIG. 5C, a phase change memory is formed by aligning and bonding the first semiconductor element 10C comprising the first wafer with the second semiconductor element 20A comprising the second wafer through the method according to one embodiment of the present invention. In the manufacturing method of the present invention, the alignment may be easily performed. In some embodiments, the first metal material layer 15, for example, may be used for forming a bit line, and the second metal material layer 17, for example, may be used for forming a word line.

In some embodiments, the first semiconductor element 10C and the second semiconductor element 20A may be manufactured by same manufacturer, or may be manufactured by different manufacturers. After the first semiconductor element 10C and second semiconductor element 20A are manufactured separately in different processes, the layer may be transferred between the first and second semiconductor elements through bonding, thereby effectively preventing the characteristic of semiconductor component such as CMOS in the second semiconductor element 20A from being degraded by a high temperature during the crystallization of a phase change material layer in the first semiconductor element 10C.

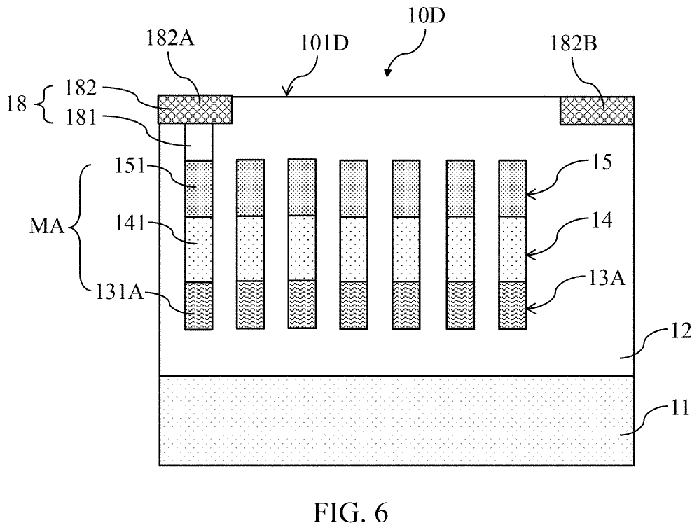

In some embodiments, before flipping the first semiconductor element, the method 200 may further comprise, as shown in FIG. 6: forming a first connection channel 18 in the first semiconductor element 10C (shown in FIG. 3D) comprising the memory array MA. The first connection channel 18 may have a first connection region 182A and a second connection region 182B electrically isolated (e.g., spaced apart) from each other. The first connection region 182A may be connected to the first metal region 151 through a connection hole 181. In one embodiment of the present invention, the connection hole 181 may be formed by etching and may be filled with a conductive material. The first connection region 182A and the second connection region 182B may be formed by depositing and patterning a conductive material layer 182. As shown in FIG. 6, a first semiconductor element 10D having the first connection channel 18 may be formed.

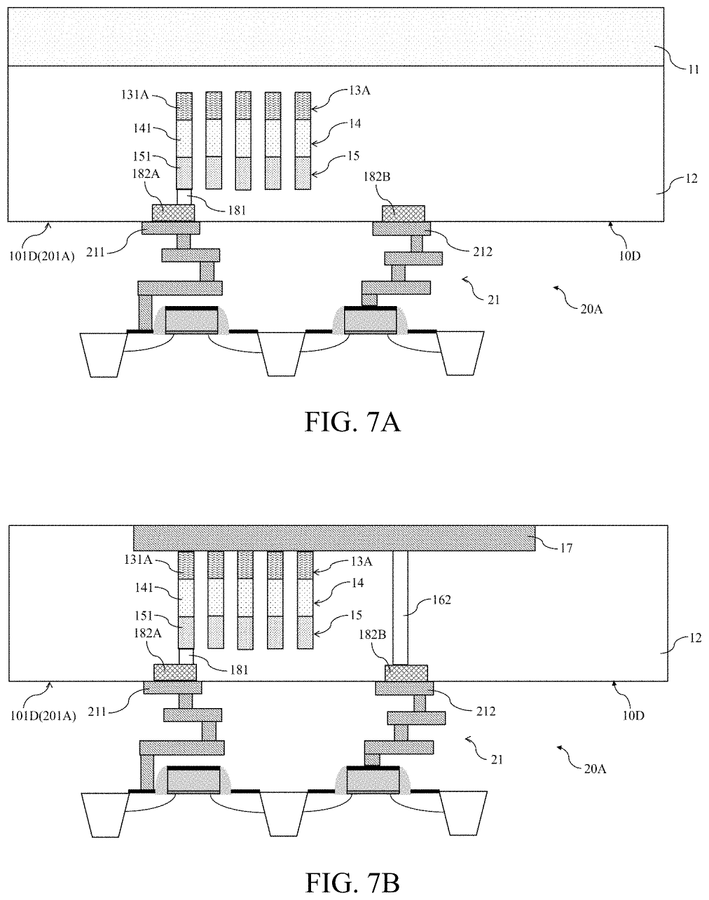

In the step S206 of the method 200, as shown in FIG. 7A, the first semiconductor element 10D as shown in FIG. 6 may be flipped and mounted on the second semiconductor element 20A. In the step S207, bonding a first surface 101D of the first semiconductor element 10D with the first surface 201A of the second semiconductor element 20A may further comprise: aligning and connecting the first connection region 182A and the second connection region 182B of the first semiconductor element 10D with the first contact region 211 and the second contact region 212 of the second semiconductor element 20A, respectively.

After the step S206, as shown in FIG. 7B, the substrate 11 of the first semiconductor element 10D may be removed to expose the insulating layer 12.

Referring to FIG. 7B, after removing the substrate 11 to expose the insulating layer 12, the method 200 may further comprise: forming a second contact hole 162 in the insulating layer 12; and forming a second metal material layer 17 in the insulating layer 12. The second metal material layer 17 is connected to the plurality of selector units 131A, and connected to the second contact region 212 of the second semiconductor element 20A through the second connection region 182B and the second contact hole 162.

According to the present invention, the alignment and bonding may be more easily performed using the structure shown in FIG. 7B.

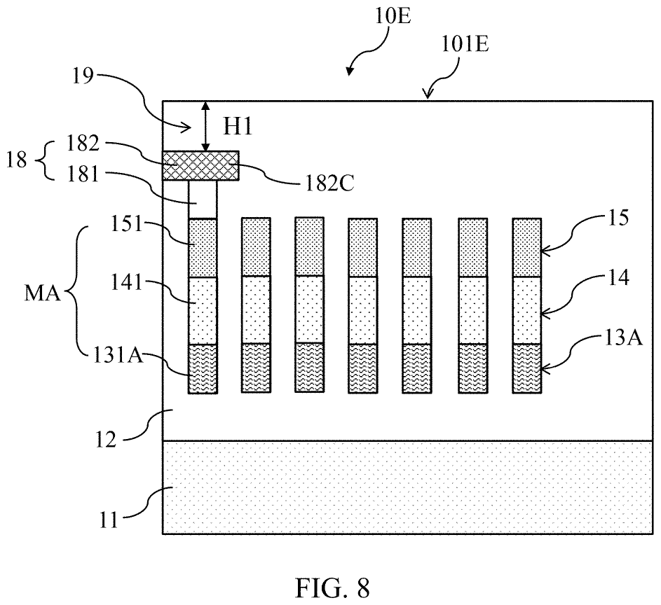

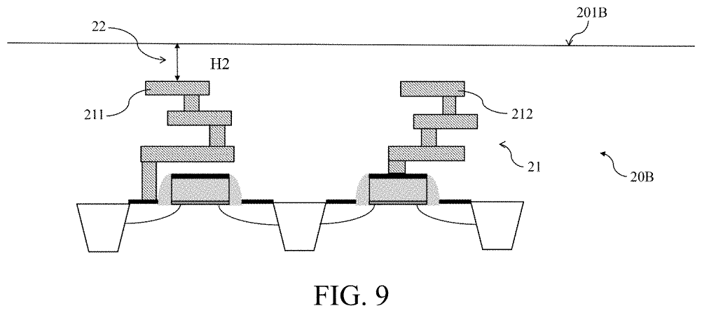

In some embodiments, before the step S206 in which the first semiconductor element is flipped, the method 200 may further comprises: as shown in FIG. 8, forming a second connection channel 18 in the first semiconductor element 10D (shown in FIG. 6) comprising the memory array MA. The second connection channel 18 may have a third connection region 182C connected to the first metal region 151 through the connection hole 181. As shown in FIG. 8, a first oxide layer 19 having a first thickness H1 is formed on the third connection region 182C. As shown in FIG. 9, a second oxide layer 22 having a second thickness H2 is formed on the first contact region 211 and the second contact region 212 of the second semiconductor element 20A (shown in FIG. 4). As shown in FIG. 8, a first semiconductor element 10E having the connection channel 18 and the first oxide layer 19 is formed. As shown in FIG. 9, a second semiconductor element 20B having the second oxide layer 22 is formed.

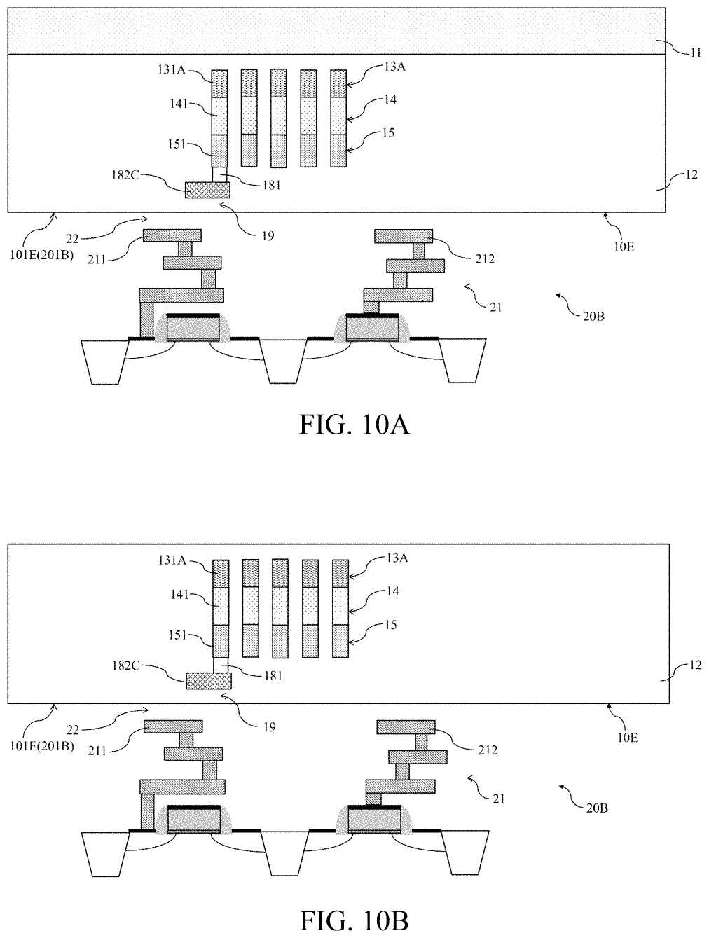

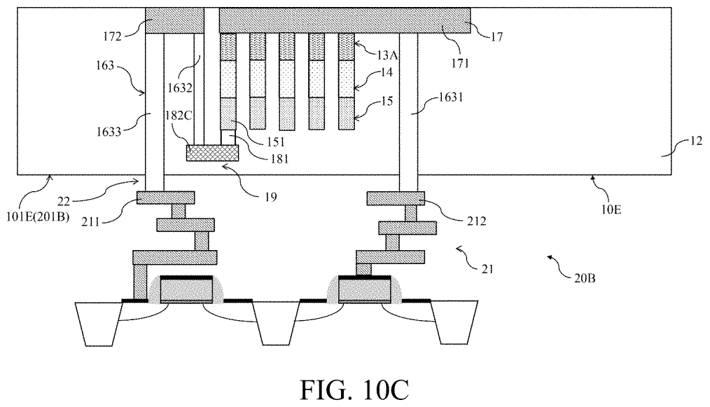

In the step S206 of the method 200, as shown in FIG. 10A, the first semiconductor element 10E as shown in FIG. 8 may be flipped and mounted on the second semiconductor element 20B as shown in FIG. 9. In the step S207, bonding a first surface 101E of the first semiconductor element 10E with a first surface 201B of the second semiconductor element 20B may further comprise: aligning the first oxide layer 19 of the first semiconductor element 10E with the second oxide layer 22 of the second semiconductor element 20B.

After the step S206, as shown in FIG. 10B, the substrate 11 of the first semiconductor element 10E may be removed to expose the insulating layer 12.

Referring to FIG. 10C, after removing the substrate 11 to expose the insulating layer 12, the method 200 may further comprise: forming a plurality of third contact holes 163 in the insulating layer 12; and forming a second metal material layer 17 in the insulating layer 12. The third contact holes 163, for example, may comprise a first third contact hole 1631, a second third contact hole 1632 and a third third contact hole 1633. The second metal material layer 17 may comprise a plurality of second metal regions having a first portion 171 and a second portion 172 electrically isolated from each other. The first portion 171 of the plurality of second metal regions is connected to the selector 13A, and connected to the second contact region 212 of the second semiconductor element 20B through the first third contact hole 1631. The second portion 172 of the plurality of second metal regions is connected to the third connection region 182C of the second connection channel 18 through the second third contact hole 1632, and connected to the first contact region 211 of the second semiconductor element 20B through the third third contact hole 1633.

In some embodiments, the first oxide layer 19 and the second oxide layer 22 may comprise the same material. According to the present invention, the alignment and bonding between the first semiconductor element 10E and the second semiconductor element 20B may be more easily performed using the structure shown in FIG. 10C.

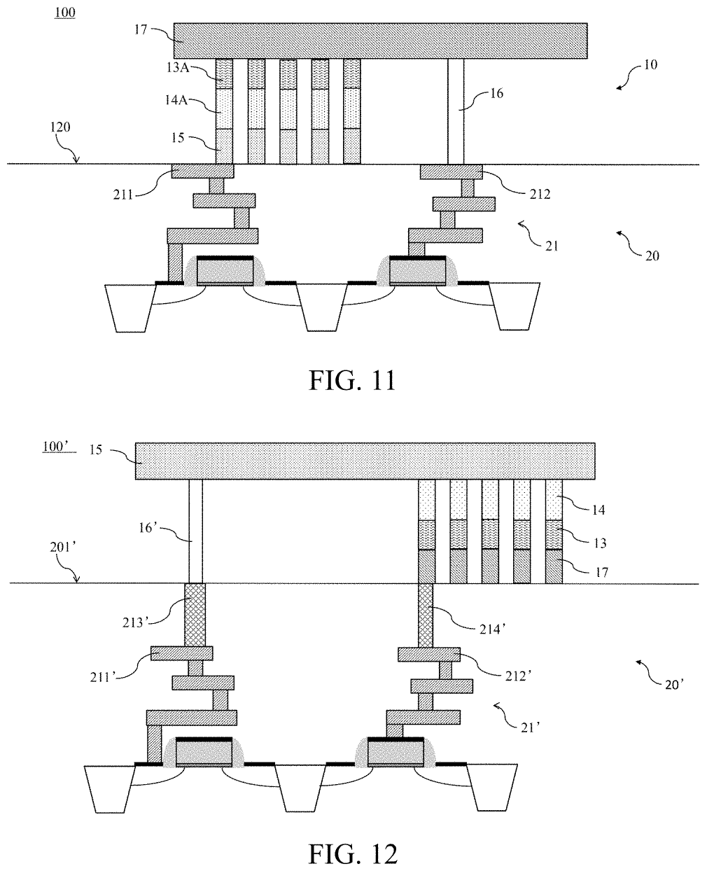

As shown in FIG. 11, in some embodiments, the memory material layer may be a non-volatile memory material layer 14A, which may comprise one or more of a voltage controlled resistor, a memory resistor and a resistor random access memory.

FIG. 12 is a diagram showing a structure of a phase change memory manufactured by a method according to prior art. In the prior art, a second metal material layer (e.g., a word line metal material layer) 17, a selector 13, a memory material layer 14 and a first metal material layer (e.g., a bit line metal material layer) 15 and the like are directly formed on a surface 201′ of a wafer 21′ of a second semiconductor element 20′. A first contact region 211′ and a second contact region 212′ of the wafer 21′ should be connected to the first metal material layer 15 and the second metal material layer 17, respectively. For example, the first contact region 211′ is connected to the first metal material layer 15 through a first connection portion 213′ and a via-hole 16′, and the second contact region 212′ is connected to the second metal material layer 17 through a second connection portion 214′. However, the alignment is difficult when connecting the first contact region 211′ and the second contact region 212′ to the first metal material layer 15 and the second metal material layer 17.

According to the present invention, the first semiconductor element comprising the first wafer and the second semiconductor element comprising the second wafer are manufactured separately, and then aligning and bonding with each other, such that an accurate alignment between the first semiconductor element and the second semiconductor element is not required, thereby simplifying the manufacturing process, lowering the manufacturing cost, and improving the manufacturing yield. Moreover, it is possible to effectively prevent the characteristic of the semiconductor component (e.g., CMOS) in the second semiconductor element from being degraded by a high temperature during the crystallization of the phase change material layer in the first semiconductor element.

Further, according to the present invention, two wafers may be easily aligned and bonded with each other by forming the P—N diode as the selector using the semiconductor-on-insulator structure, and transferring the layer between the wafers through oxide-oxide melted bonding or oxide-metal mixed bonding, thereby lowering the defect density and leakage without additional risks.

According to the present invention, an alignment area of the contact region is increased by providing the connection channel in the first semiconductor element, such that the alignment and bonding between the two elements may be easily performed.

According to the present invention, the alignment and bonding between the two elements may be easily performed by providing the oxide layer in each of the first semiconductor element and the second semiconductor element.

Although embodiments of the present invention have been described in considerable detail, other embodiments are possible. Therefore, the spirit and scope of the claim scope of the present invention should not be limited to the description of the embodiments contained herein.

It is obvious to those skilled in the art that various modifications and changes can be made to the structure of the present invention without departing from the scope or spirit of the present invention. In view of the foregoing, the present invention is intended to cover the modifications and changes of the present invention as long as they fall within the claim scope of the present invention.

What is claimed is:

1. A method for manufacturing a phase change memory, comprising:
forming a first wafer having a semiconductor-on-insulator structure;
forming a memory material layer on the semiconductor-on-insulator structure; and
forming a first metal material layer on the memory material layer to form a first semiconductor element.

2. The method of claim 1, wherein forming the first wafer comprises:
forming an insulating layer on a substrate;
forming a semiconductor layer on the insulating layer to form the semiconductor-on-insulator structure; and
performing N-type and P-type doping on the semiconductor layer to form a selector.

3. The method of claim 2, further comprising:
forming a memory array in the first semiconductor element, wherein the memory array comprises a plurality of memory units formed in the memory material layer, a plurality of selector units formed in the semiconductor-on-insulator structure, and a plurality of first metal regions formed in the first metal material layer.

4. The method of claim 3, further comprising:
forming a second semiconductor element, wherein the second semiconductor element comprises a second wafer having a first contact region and a second contact region; and
flipping the first semiconductor element and bonding a first surface of the first semiconductor element with a first surface of the second semiconductor element.

5. The method of claim 4, further comprising:
removing the substrate to expose the insulating layer after bonding the first surface of the first semiconductor element with the first surface of the second semiconductor element.

6. The method of claim 5, wherein removing the substrate comprises:
grinding, polishing and/or etching a second surface of the first semiconductor element to expose the insulating layer.

7. The method of claim 5, wherein bonding the first surface of the first semiconductor element with the first surface of the second semiconductor element comprises:
aligning and connecting the first metal region of the first semiconductor element with the first contact region of the second semiconductor element.

8. The method of claim 7, further comprising, after removing the substrate to expose the insulating layer:
forming a first contact hole in the insulating layer; and
forming a second metal material layer in the insulating layer,
wherein the second metal material layer is connected to the plurality of selector units, and connected to the second contact region of the second semiconductor element through the first contact hole.

9. The method of claim 5, further comprising:
before flipping the first semiconductor element, forming a first connection channel in the first semiconductor element comprising the memory array,
wherein the first connection channel comprises a first connection region and a second connection region electrically isolated from each other, and
wherein the first connection region is connected to the first metal region through a first connection hole.

10. The method of claim 9, wherein bonding the first surface of the first semiconductor element with the first surface of the second semiconductor element further comprises:
aligning and connecting the first connection region and the second connection region of the first semiconductor element with the first contact region and the second contact region of the second semiconductor element, respectively.

11. The method of claim 10, further comprising, after removing the substrate to expose the insulating layer:
forming a second contact hole in the insulating layer; and
forming a second metal material layer in the insulating layer,
wherein the second metal material layer is connected to the plurality of selector units, and connected to the second contact region of the second semiconductor element through the second connection region and the second contact hole.

12. The method of claim 5, further comprising, before flipping the first semiconductor element:
forming a second connection channel in the first semiconductor element comprising the memory array, wherein the second connection channel comprises a third connection region connected to the first metal region through a second connection hole;
forming a first oxide layer having a first thickness on the third connection region of the first semiconductor element; and
forming a second oxide layer having a second thickness on the first contact region and the second contact region of the second semiconductor element.

13. The method of claim 12, wherein the first oxide layer and the second oxide layer comprise same material.

14. The method of claim 12, wherein bonding the first surface of the first semiconductor element with the first surface of the second semiconductor element further comprises:
aligning the first oxide layer of the first semiconductor element with the second oxide layer of the second semiconductor element.

15. The method of claim 14, further comprising, after removing the substrate to expose the insulating layer:
forming a plurality of third contact holes in the insulating layer; and
forming a second metal material layer in the insulating layer,
wherein the second metal material layer comprises a plurality of second metal regions having a first portion and a second portion electrically isolated from each other,
wherein the first portion of the plurality of second metal regions is connected to the plurality of selector units, and connected to the second contact region of the second semiconductor element through the third contact hole, and
wherein the second portion of the plurality of second metal regions is connected to the third connection region of the second connection channel through the third contact hole, and connected to the first contact region of the second semiconductor element through the third contact hole.

16. The method of claim 1, wherein the memory material layer is a phase change memory material layer.

17. The method of claim 1, wherein the memory material layer is a non-volatile memory material layer comprising one or more of a voltage controlled resistor, a memory resistor and a resistor random access memory.

18. A phase change memory, comprising:
a first semiconductor element comprising:
a first wafer having a semiconductor-on-insulator structure;
a selector formed on the semiconductor-on-insulator structure;
a memory material layer formed on the selector; and
a first metal material layer formed on the memory material layer.

19. The phase change memory of claim 18, wherein the first semiconductor element further comprises a memory array, the memory array comprising:
a plurality of memory units formed in the memory material layer;
a plurality of selector units formed in the semiconductor-on-insulator structure; and
a plurality of first metal regions formed in the first metal material layer.

20. The phase change memory of claim 19, wherein the first wafer comprises:
an insulating layer formed on a removable substrate,
wherein the selector is formed by forming a semiconductor layer on the insulating layer to form the semiconductor-on-insulator structure, and performing N-type and P-type doping on the semiconductor layer.

21. The phase change memory of claim 20, further comprising:
a second semiconductor element comprising:
a second wafer having a first contact region and a second contact region,
wherein the first semiconductor element is flipped and mounted on the second semiconductor element, and a first surface of the first semiconductor element is bonded with a first surface of the second semiconductor element.

22. The phase change memory of claim 21, wherein the first metal region of the first semiconductor element is aligned and connected with the first contact region of the second semiconductor element.

23. The phase change memory of claim 22, wherein the first semiconductor element further comprises:
a first contact hole formed in the insulating layer; and
a second metal material layer formed in the insulating layer,
wherein the second metal material layer is connected to the plurality of selector units, and connected to the second contact region of the second semiconductor element through the first contact hole.

24. The phase change memory of claim 23, wherein the first metal material layer is a metal material layer for forming a bit line, and the second metal material layer is a metal material layer for forming a word line.

25. The phase change memory of claim 21, wherein the first semiconductor element further comprises:
a first connection channel having a first connection region and a second connection region electrically isolated from each other,
wherein the first connection region is connected to the first metal region through a first connection hole, and
wherein the first connection region and the second connection region of the first semiconductor element are aligned and connected with the first contact region and the second contact region of the second semiconductor element, respectively.

26. The phase change memory of claim 25, wherein the first semiconductor element further comprises:
a second contact hole formed in the insulating layer; and
a second metal material layer formed in the insulating layer,
wherein the second metal material layer is connected to the plurality of selector units, and connected to the second contact region of the second semiconductor element through the second connection region and the second contact hole.

27. The phase change memory of claim 26, wherein the first metal material layer is a metal material layer for forming a bit line, and the second metal material layer is a metal material layer for forming a word line.

28. The phase change memory of claim 21, wherein the first semiconductor element further comprises:
a second connection channel having a third connection region connected to the first metal region through a second connection hole; and
a first oxide layer formed on the third connection region of the first semiconductor element,
wherein the first oxide layer of the first semiconductor element is aligned and bonded with a second oxide layer formed on the first contact region and the second contact region of the second semiconductor element.

29. The phase change memory of claim 28, wherein the first oxide layer and the second oxide layer comprise same material.

30. The phase change memory of claim 28, wherein the first semiconductor element further comprises:
a plurality of third contact holes formed in the insulating layer; and
a second metal material layer formed in the insulating layer, the second metal material layer comprising a plurality of second metal regions having a first portion and a second portion electrically isolated from each other,
wherein the first portion of the plurality of second metal regions is connected to the plurality of selector units, and connected to the second contact region of the second semiconductor element through the third contact hole, and
wherein the second portion of the plurality of second metal regions is connected to the third connection region of the second connection channel through the third contact hole, and connected to the first contact region of the second semiconductor element through the third contact hole.

31. The phase change memory of claim 30, wherein the first metal material layer is a metal material layer for forming a bit line, and the second metal material layer is a metal material layer for forming a word line.

32. The phase change memory of claim 18, wherein the memory material layer is a phase change memory material layer.

33. The phase change memory of claim 18, wherein the memory material layer is a non-volatile memory material layer comprising one or more of a voltage controlled resistor, a memory resistor and a resistor random access memory.
